(19) United States
(12) Patent Application Publication
(10) Pub. No.: US 2026/0053024 A1
(43) Pub. Date: Feb. 19, 2026

(54) SEMICONDUCTOR PACKAGE AND WAFER STRUCTURE

(71) Applicant: Samsung Electronics Co., Ltd., Suwon-si (KR)

(72) Inventor: Jaewon Kim, Suwon-si (KR)

(21) Appl. No.: 19/054,955

(22) Filed: Feb. 17, 2025

(30) Foreign Application Priority Data
Aug. 19, 2024 (KR) 10-2024-0110401

(51) Int. Cl. H01L 23/498; H01L 23/00; H01L 23/31

(52) U.S. Cl. CPC H01L 23/49838; H01L 23/49816; H01L 24/16; H01L 24/20; H01L 24/97; H01L 23/3128; H01L 2224/16227; H01L 2224/211; H01L 2224/97

(57) ABSTRACT

The present disclosure as an embodiment provides a semiconductor package including a first redistribution structure; conductive bumps arranged on a lower surface of the first redistribution structure; a semiconductor chip arranged on an upper surface of the first redistribution structure; an encapsulant that encapsulates at least a portion of the semiconductor chip; a second redistribution structure disposed on the encapsulant and including an insulating layer and a first wiring layer including a first conductive pattern exposed to a side surface of the insulating layer; and a conductive post that penetrates the encapsulant to electrically connect the first redistribution structure and the second redistribution structure.

### CROSS-REFERENCE TO RELATED APPLICATION

This application claims priority to and the benefit of Korean Patent Application No. 10-2024-0110401 filed in the Korean Intellectual Property Office on Aug. 19, 2024, the entire contents of which are incorporated herein by reference.

### BACKGROUND OF THE DISCLOSURE

### (a) Field of the Disclosure

The present disclosure relates to a semiconductor package and a wafer structure.

### (b) Description of the Related Art

As semiconductor packages become more high-performance, highly integrated, and smaller sized, increased attention is being placed to ensure the quality and reliability of the semiconductor packages. An electrostatic discharge (ESD) generated during the manufacturing process of the semiconductor packages may deteriorate the quality and reliability of the semiconductor package, and methods and structures to minimize these are helpful.

### SUMMARY OF THE DISCLOSURE

The present disclosure seeks, in one aspect, to provide a semiconductor package and a wafer structure capable of preventing or reducing a movement of conductive bumps.

The present disclosure, in another aspect, seeks to provide a semiconductor package and a wafer structure capable of preventing (or reducing) wire burning defects in semiconductor chips.

In one example, a semiconductor package is provided including a first redistribution structure; conductive bumps arranged on a lower surface of the first redistribution structure; a semiconductor chip arranged on an upper surface of the first redistribution structure; an encapsulant that encapsulates at least a portion of the semiconductor chip; a second redistribution structure disposed on the encapsulant and including an insulating layer and a first wiring layer including a first conductive pattern exposed to a side surface of the insulating layer; and a conductive post that penetrates the encapsulant to electrically connect the first redistribution structure and the second redistribution structure.

In another example, a semiconductor package is provided including a first redistribution structure; conductive bumps arranged on a lower surface of the first redistribution structure; a semiconductor chip arranged on an upper surface of the first redistribution structure; an encapsulant that encapsulates at least a portion of the semiconductor chip; a second redistribution structure disposed on the encapsulant, and including an insulating layer, a first wiring layer including a first conductive pattern, and a second conductive pattern disposed on the first conductive pattern; and a conductive post that penetrates the encapsulant to electrically connect the first redistribution structure and the second redistribution structure, wherein the first conductive pattern is electrically connected to a conductive bump arranged in an edge region of the first redistribution structure among the conductive bumps, and the second conductive pattern is electrically connected to the first conductive pattern and is exposed to an upper surface of the insulating layer.

In another example, a wafer structure is provided having chip regions and a scribe lane region disposed between the chip regions and including a first redistribution structure extended to the chip regions and the scribe lane region; conductive bumps arranged on a lower surface of the first redistribution structure in each of the chip regions; semiconductor chips each arranged on an upper surface of the first redistribution structure in each of the chip regions; an encapsulant that extends to the chip regions and the scribe lane region and encapsulates at least a portion of each of the semiconductor chips; a second redistribution structure disposed on the encapsulant so as to extend to the chip regions and the scribe lane region and including an insulating layer and a wiring layer including a first conductive pattern; and a conductive post electrically connecting the first redistribution structure and the second redistribution structure by penetrating the encapsulant in each of the chip regions, wherein the chip regions include a first chip region and a second chip region adjacent to each other, and the first conductive pattern is positioned to extend to the first chip region, the second chip region, and a region positioned between the first chip region and the second chip region of the scribe lane region.

According to one aspect of the present disclosure, the semiconductor package and the wafer structure capable of preventing or reducing the movement of the conductive bump may be provided.

According to another aspect of the present disclosure, the semiconductor package and the wafer structure capable of preventing (or reducing) wire burning defects of the semiconductor chip may be provided.

### BRIEF DESCRIPTION OF THE DRAWINGS

FIG. 1 is a view showing chip regions and a scribe lane region of a wafer structure.

FIG. 2 is a view showing a wafer structure fixed on a table according to a comparative example.

FIG. 3 and FIG. 4 are views showing a change in an electron arrangement in a region A of a wafer structure according to a comparative example.

FIG. 5 to FIG. 8 are views showing defects that occur when a conductive bump moves in a wafer structure.

FIG. 9 is a cross-sectional view of a region of a wafer structure according to an embodiment.

FIG. 10 is a view showing a wafer structure fixed on a table according to an embodiment.

FIG. 11 is a view showing a movement path of electrons in a region B of a wafer structure according to an embodiment.

FIG. 12 to FIG. 22 are views showing a manufacturing method of a wafer structure according to an embodiment.

FIG. 23 is a view showing a process of sawing a wafer structure.

FIG. 24 is a cross-sectional view of a semiconductor package according to an embodiment.

FIG. 25 is a bottom view of a semiconductor package illustrated in FIG. 24.

FIG. 26 is a cross-sectional view of a semiconductor package according to another embodiment.

FIG. 27 is a cross-sectional view of a semiconductor package according to another embodiment.

FIG. 28 is a cross-sectional view of a semiconductor package according to another embodiment.

FIG. 29 is a cross-sectional view of a semiconductor package according to another embodiment.

FIG. 30 is a cross-sectional view of a semiconductor package according to another embodiment.

FIG. 31 is a cross-sectional view of a semiconductor package according to another embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways without departing from the spirit or scope of the present disclosure.

Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled” to another element, the element may be “directly coupled” to the other element or “indirectly coupled” to the other element through a third element. From a similar perspective, this includes not only being “physically connected”but also being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Additionally, throughout the specification, the sequential numbers, such as a first, a second, etc., are used to distinguish a component from other identical or similar components, and are not necessarily intended to refer to a specific component. Thus, a component referred to as a first component in a particular part of this specification may be referred to as a second component in another part of this specification.

Additionally, throughout the specification, a singular reference to any component includes a plurality of references to that component, unless otherwise stated. Additionally, a configuration described as a plurality of components in the specification may be implemented by changing it to a singular component depending on the embodiment.

Additionally, throughout the specification, references to the upper and lower surfaces of any configuration will be made with reference to the drawings.

Hereinafter, a semiconductor package and a wafer structure according to embodiments of the present disclosure are described with reference to drawings.

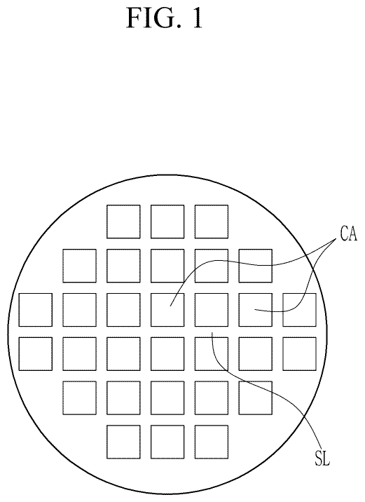

FIG. 1 is a view showing chip regions and a scribe lane region of a wafer structure.

A wafer structure may have chip regions CA and a scribe lane region SL positioned between them. The wafer structure may be separated into a plurality of individual semiconductor packages by being sawed (sawing) with a blade, a laser, etc. along the scribe lane region SL. The chip regions CA that constitute each semiconductor package may include components (semiconductor chips, redistribution structures (RDLs), encapsulating materials, etc.) for functioning as a semiconductor package. The present disclosure seeks to prevent a charge imbalance in the wafer structure and, as an embodiment, to form an electron movement path in the scribe lane region SL.

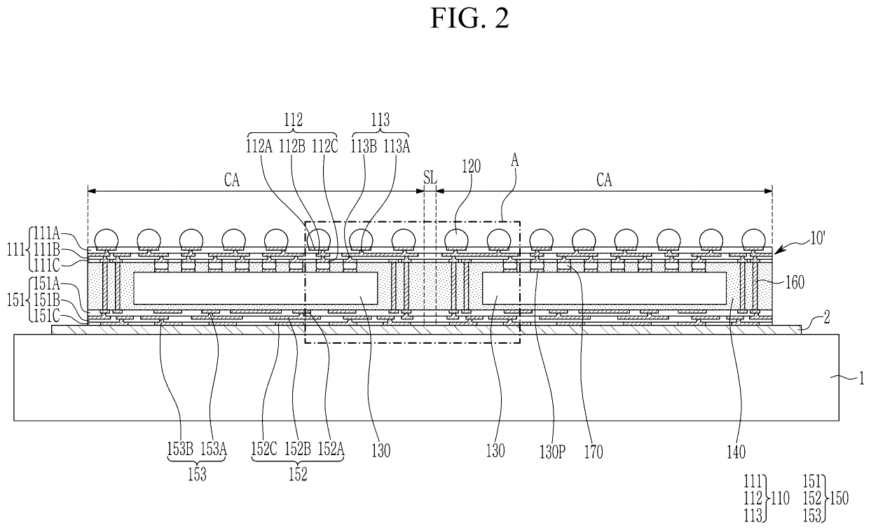

FIG. 2 is a view showing a wafer structure fixed on a table according to a comparative example.

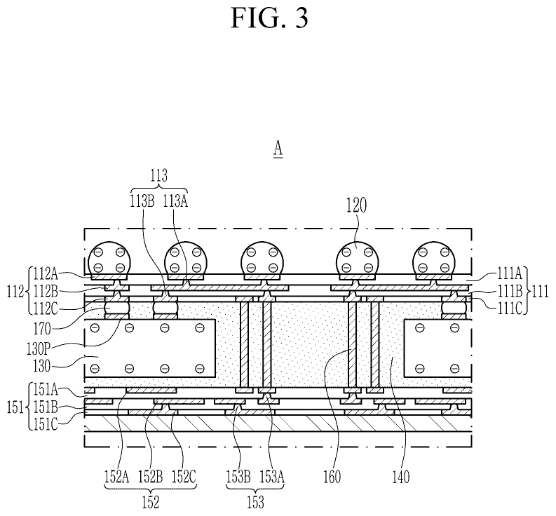

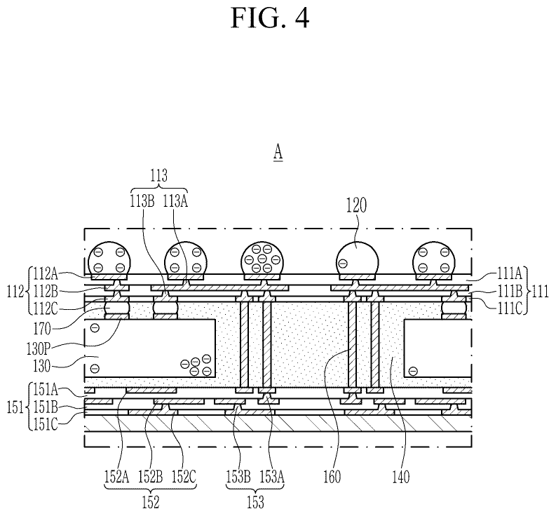

FIG. 3 and FIG. 4 are views showing a change in an electron arrangement in a region A of a wafer structure according to a comparative example.

FIG. 3 shows an exemplary arrangement of electrons when the wafer structure is fixed on the table. FIG. 4 shows an exemplary arrangement of electrons when the wafer structure is detached from the table.

Referring to FIG. 2, in the wafer structure 10′ according to the comparative example, each chip region CA may not be electrically connected to the other chip region CA and/or the table 1. According to the comparative example, a charge imbalance of the wafer structure 10′ may occur during the manufacturing process of the semiconductor package due to the inability of the electrons to move to the outside of each chip region CA in the wafer structure 10′. For example, when the wafer structure 10′ is fixed on the table 1 while attached to the tape 2 (e.g., a vacuum adsorption) and then detached, the charge imbalance of the wafer structure 10′ may occur due to the electrons being concentrated on one side by a static electricity (an electrostatic discharge; ESD) (e.g., a peeling charging) (referring to FIG. 3 and FIG. 4).

The electrons tend to be gathered at the edge region (particularly the corner region) of the chip region CA, and a shift of the conductive bump 120 may occur due to a repulsive force (a coulomb repulsive force) between the electrons concentrated at the edge regions of the adjacent chip regions CA. In addition, the electrons densely packed in the edge region of the semiconductor chip 130 may be trapped within the semiconductor chip 130, causing an excessive voltage or overcurrent to be applied, thereby causing a burning phenomenon in the wire.

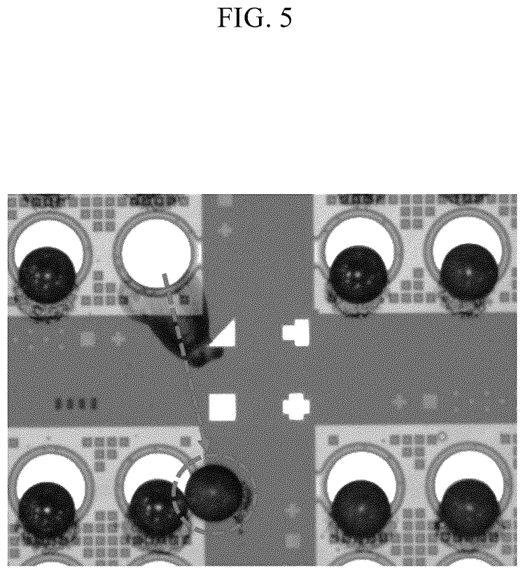

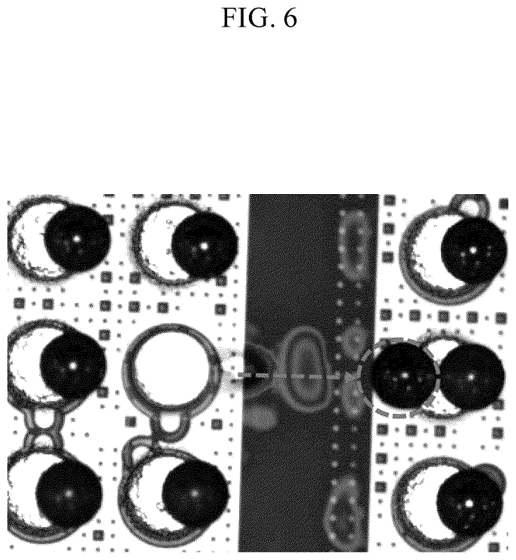

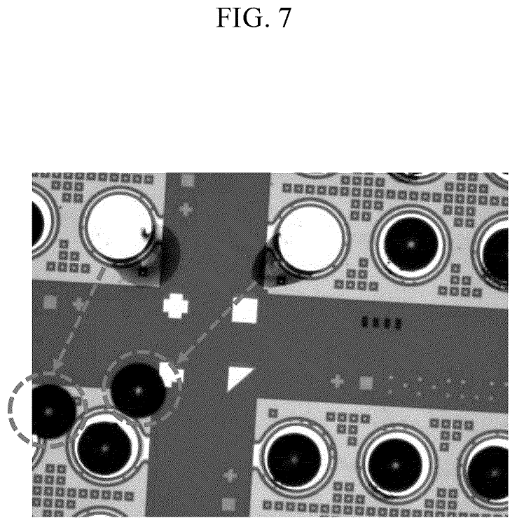

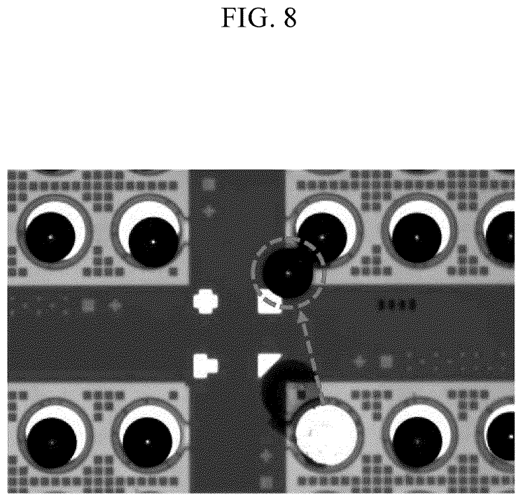

FIG. 5 to FIG. 8 are views showing defects that occur when a conductive bump moves in a wafer structure.

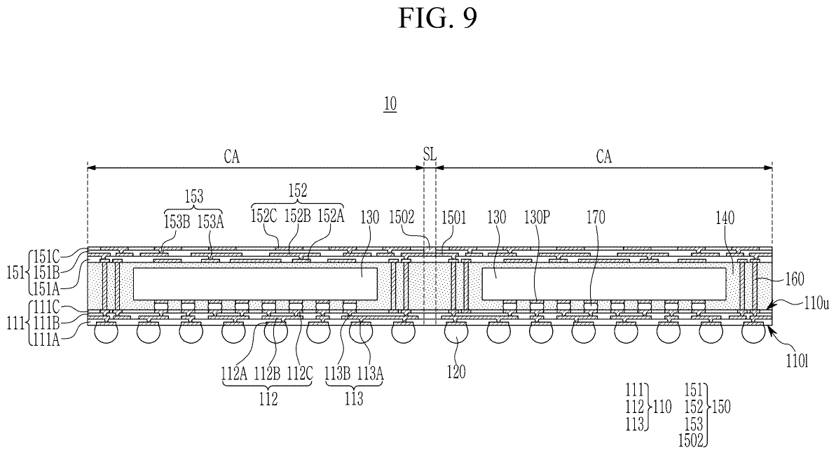

Referring to the drawings, it may be seen that in actual products that do not include conductive patterns 1501 and 1502 (FIG. 9) according to the present disclosure, conductive bumps positioned at edge regions (particularly corner regions) of adjacent chip regions move outward from the chip regions. The movement of these conductive bumps may cause a reliability deterioration, a quality deterioration, and a yield deterioration of the product.

FIG. 9 is a cross-sectional view of a region of a wafer structure according to an embodiment.

For convenience of an illustration, FIG. 9 shows only the adjacent chip regions and the scribe lane region located between them in the wafer structure.

The present disclosure seeks to prevent the charge imbalance in the wafer structure 10 by providing a migration path for the electrons between the chip regions CA and/or from the chip region CA to the outside (e.g., the table 1) of the wafer structure 10. The wafer structure 10 according to an embodiment may include a first conductive pattern 1501 providing the electron migration path between the chip regions CA and/or a second conductive pattern 1502 providing the electron migration path from the chip region CA to the outside of the wafer structure 10.

Hereinafter, the wafer structure 10 according to an embodiment is described in detail with reference to the drawings.

The wafer structure 10 may have chip regions CA and a scribe lane regions SL disposed between them.

Also, the wafer structure 10 may include a first redistribution structure 110, conductive bumps 120 disposed on the lower surface 110l of the first redistribution structure 110, semiconductor chips 130 disposed on the upper surface 110u of the first redistribution structure 110, an encapsulant 140 encapsulating at least a portion of each of the semiconductor chips 130, a second redistribution structure 150 disposed on the encapsulant 140, and conductive posts 160 penetrating the encapsulant 140 and electrically connecting the first redistribution structure 110 and the second redistribution structure 150.

The first redistribution structure 110 may be arranged to be extended to the chip regions CA and the scribe lane region SL.

The first redistribution structure 110 may include insulating layers 111, wiring layers 112, and vias 113. For example, the first redistribution structure 110 may include a first wiring layer 112A, a first insulating layer 111A covering the first wiring layer 112A, a second wiring layer 112B arranged on the first insulating layer 111A, first vias 113A electrically connecting the first wiring layer 112A and the second wiring layer 112B by penetrating the first insulating layer 111A, a second insulating layer 111B positioned on the first insulating layer 111A and covering the second wiring layer 112B, a third wiring layer 112C located on the second insulating layer 111B, second vias 113B electrically connecting the second wiring layer 112B and the third wiring layer 112C by penetrating the second insulating layer 111B, and a third insulating layer 111C disposed on the second insulating layer 111B, covering at least a portion of the third wiring layer 112C and exposing at least a portion of the third wiring layer 112C.

The insulating layers 111 may be located between the wiring layers 112 to prevent electric shorts between them. The insulating layers 111 may have boundaries with each other or may not have boundaries that can be seen with the naked eye, depending on their materials and manufacturing processes. The third insulating layer 111C, which is located on the topmost side of the insulating layers 111, may serve as a passivation film that electrically, mechanically, and chemically protects the wiring layer. An insulating material may be used as the material of the insulating layer 111, for example, polyimide (PI), epoxy, PID (Photo-Imageable Dielectric), etc. may be used.

The wiring layer layers 112 may include wire pattern(s), and the wire patterns may be connected to each other to perform various functions according to a design. For example, the wiring layers 112 may include at least one of a signal wire performing a signal transmission function, a power wire performing a power transmission function, and a ground wire performing a ground function. The first wiring layer 112A, which is positioned at the bottom of the wiring layers 112, may include wire pads for an electrical connection with the conductive bumps 120. Additionally, the third wiring layer 112C, which is positioned on the top of the wiring layers 112, may include wire pads for an electrical connection with the semiconductor chip 130 and/or the conductive post 160. The number of the wiring layers 112 is not limited and may be more or less than those shown in the drawing. In addition, a conductive material may be used as the material of the wiring layers 112, and for example, copper (Cu), aluminum (Al), gold (Au), silver (Ag), platinum (Pt), tin (Sn), chromium (Cr), palladium (Pd), lead (Pb), titanium (Ti), tungsten (W) or an alloy thereof may be used.

The vias 113 may provide electrical connections between the wiring layers 112 positioned at different layers. A conductive material may be used as the material for the vias 113, and the same material as the material for the wiring layers 112 may be used. According to a manufacturing process, the vias 113 may be integrally formed with the wiring layers 112, so that no boundary exists between them. Additionally, the vias 113 may have a tapered shape with the width becoming narrower from one side to the other side, a circular cylinder shape, etc.

The conductive bumps 120 may be arranged on the lower surface 110l of the first redistribution structure 110 in each chip region CA. The conductive bumps 120 may be, for example, solder balls. The size, number, spacing, etc. of the conductive bumps 120 are not particularly limited and may be implemented in various ways depending on the design.

Each semiconductor chip 130 may be located on the upper surface 110u of the first redistribution structure 110 in each of the chip regions CA. The semiconductor chip 130 may include a connection pad 130P, and the connection pad 130P may be positioned in a face down configuration on an upper surface 110u of the first redistribution structure 110 so as to face the first redistribution structure 110. The semiconductor chips 130 may be mounted on the first redistribution structure 110 via the conductive bumps 170, such as solder balls. However, according to an embodiment, the semiconductor chip 130 may be arranged in a face up configuration so that the connection pad 130P faces the second redistribution structure 150.

The type of the semiconductor chip 130 is not particularly limited, and the semiconductor chip 130 may include at least one of, for example, a logic chip and a memory chip. The logic chip may include, for example, one or more of a central processing unit (CPU), a graphic processing unit (GPU), a neural processing unit (NPU), an application specific integrated circuit (ASIC), an application processor (AP), a microprocessor, and a system on chip (SoC). The memory chip may include, for example, one or more of a dynamic random access memory (DRAM) chip, a static random access memory (SRAM) chip, a flash memory chip, a high bandwidth memory (HBM) chip, a read-only memory (ROM) chip, and a magnetic random access memory (MRAM) chip.

The encapsulant 140 is arranged to extend to the chip regions CA and the scribe lane region SL, and may encapsulate at least a portion of each of the semiconductor chips 130. An insulating material may be used as the material for encapsulant 140, for example, an epoxy molding compound (EMC) may be used.

The second redistribution structure 150 may be located on the encapsulant 140 to extend to the chip region CA and the scribe lane region SL.

The second redistribution structure 150 may include insulating layers 151, wiring layers 152, and vias 153. For example, the second redistribution structure 150 may include a first wiring layer 152A, a first insulating layer 151A covering the first wiring layer 152A, a second wiring layer 152B arranged on the first insulating layer 151A, first vias 153A penetrating the first insulating layer 151A and electrically connecting the first wiring layer 152A and the second wiring layer 152B, a second insulating layer 151B arranged on the first insulating layer 151A and covering the second wiring layer 152B, a third wiring layer 152C arranged on the second insulating layer 151B, second vias 153B penetrating the second insulating layer 151B and electrically connecting the second wiring layer 152B and the third wiring layer 152C, and a third insulating layer arranged on the second insulating layer 151B and covering at least a portion of the third wiring layer 152C and exposing at least a portion of the third wiring layer 152C.

The insulating layer 151 may be disposed between the wiring layers 152 to prevent electric shorts between them. The insulating layers 151 may have boundaries with each other or may not have boundaries that can be seen with the naked eye, depending on the material and manufacturing process thereof. The third insulating layer 151C, which is located on the topmost side of the insulating layers 151, may serve as a passivation film that electrically, mechanically, and chemically protects the wiring layer. An insulating material may be used as the material of the insulating layer 151, for example, polyimide (PI), epoxy, photo-imageable dielectric (PID), etc. may be used.

The wiring layers 152 may include wire pattern(s), and the wire patterns can be connected to each other to perform various functions depending on a design. For example, the wiring layers 152 may include at least one of a signal wire performing a signal transmission function, a power wire performing a power transmission function, and a ground wire performing a ground function. The first wiring layer 152A, which is positioned at the bottom of the wiring layers 152, may include wire pads for electrical connection to the conductive posts 160. According to an embodiment, the first wiring layer 152A may be connected to the conductive post 160 through a via. Additionally, the third wiring layer 152C, which is positioned on the top of the wiring layers 152, may include wire pads for an electrical connection with other components such as other semiconductor packages. The number of the wiring layers 152 is not limited and may be more or less than those shown in the drawing. In addition, a conductive material may be used as the material of the wiring layer 152, for example copper (Cu), aluminum (Al), gold (Au), silver (Ag), platinum (Pt), tin (Sn), chromium (Cr), palladium (Pd), lead (Pb), titanium (Ti), tungsten (W) or an alloy thereof may be used.

The vias 153 may provide an electrical connection between the wiring layers 152 positioned at different layers. A conductive material may be used as the material for vias 153, and the same material as the material for the wiring layer 152 may be used. According to a manufacturing process, the vias 153 may be integrally formed with the wiring layers 152, so that no boundary exists between them. Additionally, the vias 153 may have a tapered shape that the width becomes narrower from one side to the other, a circular cylinder shape, etc.

In an embodiment, the second redistribution structure 150 may include a first conductive pattern 1501 that is positioned to extend between the adjacent chip regions CA and to the scribe lane region SL disposed therebetween, thereby providing an electrical connection path between the chip regions CA.

The first conductive pattern 1501 may be included in any one of the wiring layers 152, for example in the second wiring layer 152B. By utilizing the wire pattern of the wiring layer 152 to provide an electrical connection path between the chip regions CA, an additional process time and an increased cost due to the formation of the first conductive pattern 1501 may be prevented.

The first conductive pattern 1501 may be electrically connected to each of the conductive bumps 120 arranged in the adjacent chip regions CA. For example, the first conductive pattern 1501 may be electrically connected to conductive bump(s) arranged in the first chip region and conductive bump(s) arranged in the second chip region adjacent to the first chip region. In an embodiment, the first conductive pattern 1501 can be electrically connected to conductive bump(s) arranged in the edge region of the chip region CA (a region adjacent to another chip region). In an embodiment, the first conductive pattern 1501 may be electrically connected to conductive bump(s) positioned at the corner region of the chip region CA (the region typically adjacent to a plurality of other chip regions). By connecting the conductive bump 120 to the first conductive pattern 1501, which provides an electron migration path, it may be prevented that the movement of the conductive bump 120 occurs by crowding the electrons on the conductive bump 120.

The first conductive pattern 1501 may be electrically connected to each of the semiconductor chips 130 arranged in the adjacent chip regions CA. By connecting the semiconductor chip 130 to the first conductive pattern 1501, which provides the electron movement path, it is possible to prevent the electrons from being concentrated on one side of the semiconductor chip 130, thereby causing a burning phenomenon of the wire.

However, the configuration electrically connected to the first conductive pattern 1501 is not limited to the conductive bump 120 and/or the semiconductor chip 130, and may be connected to other configurations in which electrons of the wafer structure 10 may be densely packed.

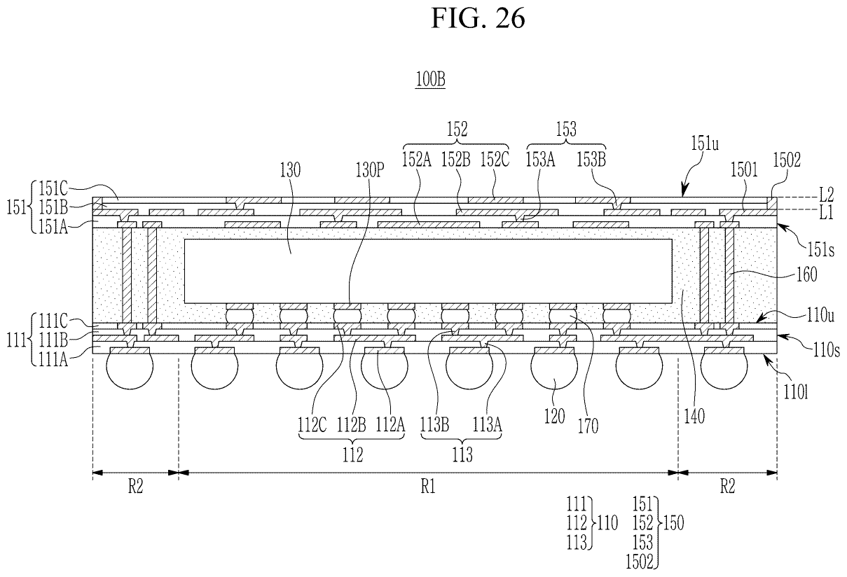

The first conductive pattern 1501 may form a ground wire. By providing the first conductive pattern 1501 utilizing the wire pattern that constitutes the ground wire, in the semiconductor package, even if the first conductive pattern 1501 is exposed at the side after sawing or otherwise separating the wafer into individual semiconductor packages (e.g. exposed proximate to the exposed side surface 151s of the insulating layer 151), and/or the second conductive pattern 1502 connected thereto is exposed where upper surface 151u (see e.g. FIGS. 26 to 28) of the insulating layer 151 is not present, a quality deterioration due to a noise or a signal interference may be prevented.

The second redistribution structure 150 may further include a second conductive pattern 1502 that is exposed through the upper surface 151u of the third insulating layer 151C, thereby providing an electron migration path from the chip region CA to the exterior of the wafer structure 10.

The second conductive pattern 1502 may be arranged on the first conductive pattern 1501 and may be electrically connected to the first conductive pattern 1501. In an embodiment, the second conductive pattern 1502 may be formed directly on the first conductive pattern 1501 to be in contact with the first conductive pattern 1501. Therefore, the second conductive pattern 1502 may be directly physically and electrically connected to the first conductive pattern 1501.

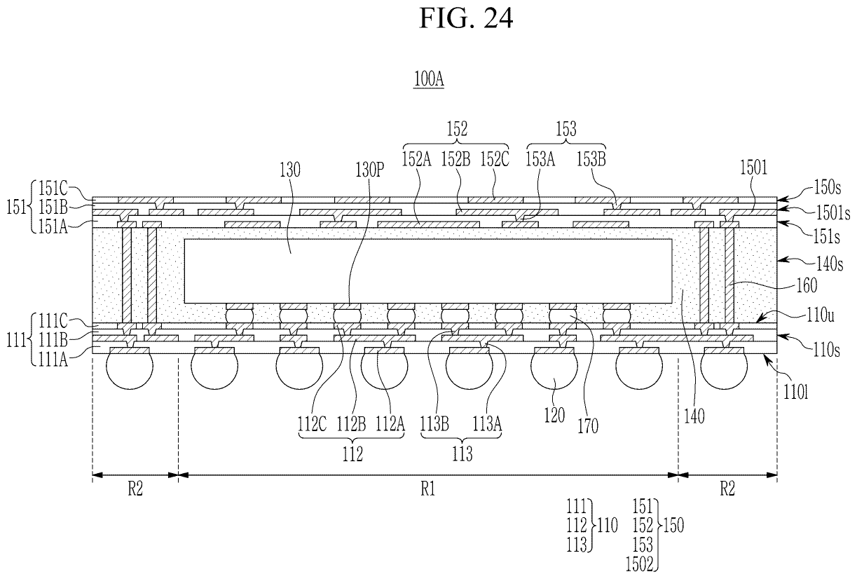

In an embodiment, the second conductive pattern 1502 can be positioned within the scribe lane region SL. Therefore, the second conductive pattern 1502 may be removed after sawing the wafer structure 10 and may not remain in the semiconductor package (see FIG. 24).

In another embodiment, the second conductive pattern 1502 may be extended across the scribe lane region SL and the chip region CA. Therefore, a part of the second conductive pattern 1502 may remain in the semiconductor package after the sawing of the wafer structure 10 (referring to FIG. 26).

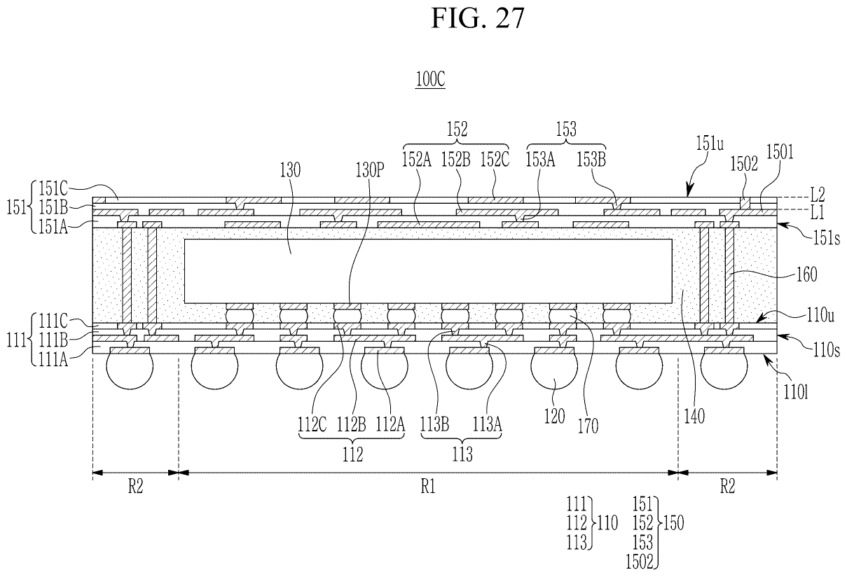

In another embodiment, each of the second conductive patterns 1502 may be positioned within each of the chip regions CA and spaced apart from one another. For example, the second conductive patterns 1502 may include a second conductive pattern disposed on the first conductive pattern 1501 within the first chip region and a second conductive pattern disposed on the first conductive pattern 1501 within the second chip region adjacent to the first chip region. Therefore, each of the second conductive patterns 1502 may remain in the semiconductor package after the sawing of the wafer structure 10 (referring to FIG. 27).

The second conductive pattern 1502 may be formed along with the via 153 and the wiring layer 152 formed on the second wiring layer 152B including the first conductive pattern 1501, for example, the second via 153B and the third wiring layer 152C. Therefore, the second conductive pattern 1502 may be extended between a level L1, where the lower surface of the second via 153B is positioned, and a level L2, where the upper surface of the third wiring layer 152C is positioned. Additionally, the second conductive pattern 1502 may include a region embedded in the second insulating layer 151B together with the second via 153B and a region embedded in the third insulating layer 151C together with the third wiring layer 152C. The width in the region embedded in the second insulating layer 151B of the second conductive pattern 1502 and the width in the region embedded in the third insulating layer 151C on the cross-section may be the same as or different from each other. By forming the second conductive pattern 1502 together with the via 153B and the third wiring layer 152C, an additional process time and cost increase due to the formation of the second conductive pattern 1502 may be prevented.

The conductive post 160 may electrically connect the first redistribution structure 110 and the second redistribution structure 150 by penetrating the encapsulant 140 in each of the chip regions CA. The material for the conductive post 160 may be a conductive material such as copper (Cu) or aluminum (Al). The conductive post 160 may be formed, for example, by plating a conductive material on the first redistribution structure 110. The conductive post 160 could be covered by the encapsulant 140, and if necessary, the encapsulant 140 may be ground to expose the conductive post 160.

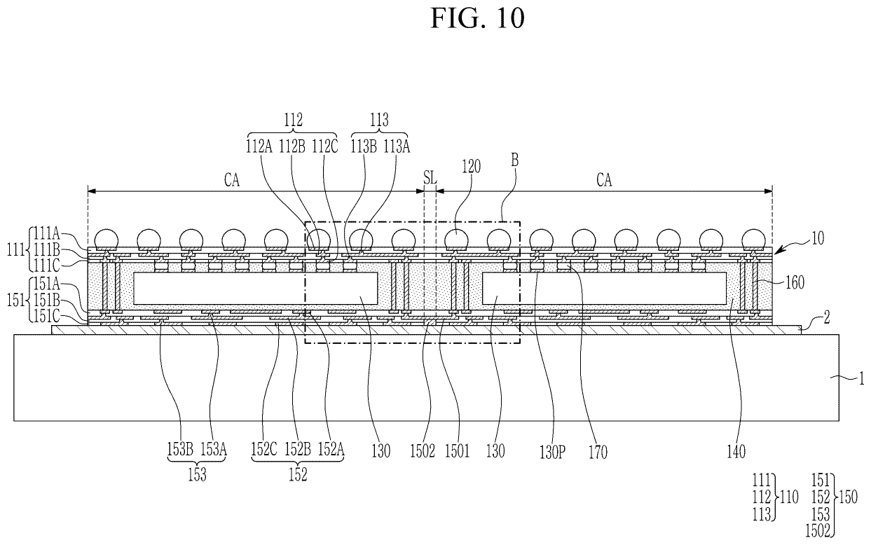

FIG. 10 is a view showing a wafer structure fixed on a table according to an embodiment.

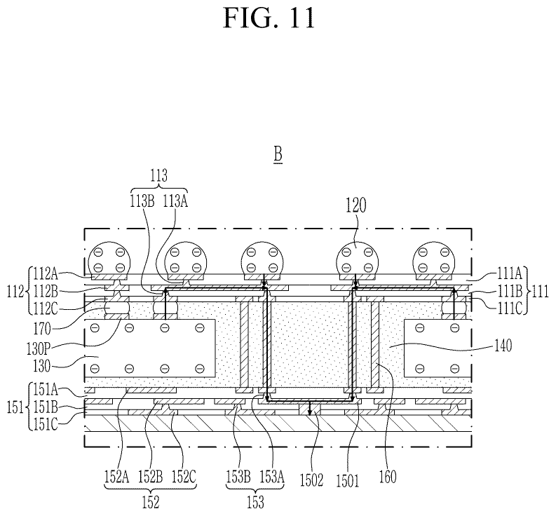

FIG. 11 is a view to explain a movement path of electrons in a region B of a wafer structure according to an embodiment.

Referring to the drawing, the electrons of the wafer structure 10 may move between the chip regions CAs through the first conductive pattern 1501 and the second conductive pattern 1502, and may be discharged to the outside (e.g., the table 1) of wafer structure 10, and the charge imbalance may be prevented from occurring within the wafer structure 10.

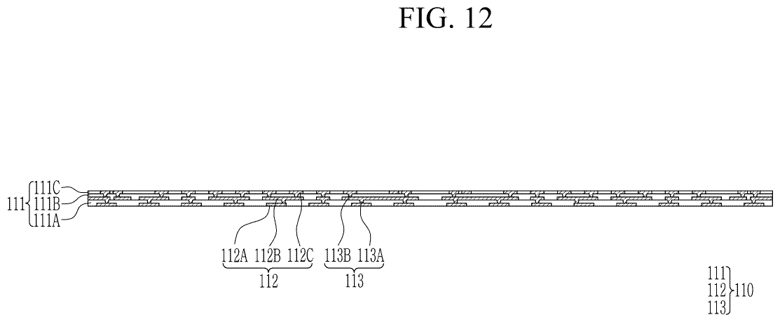

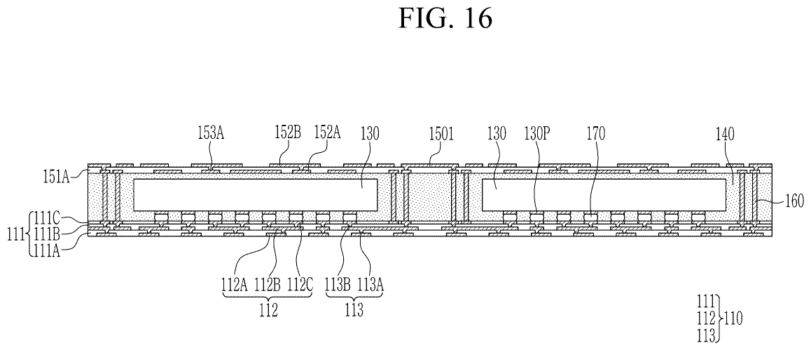

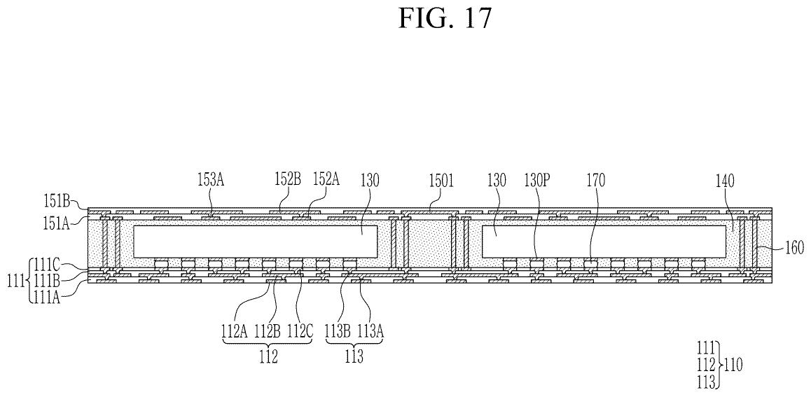

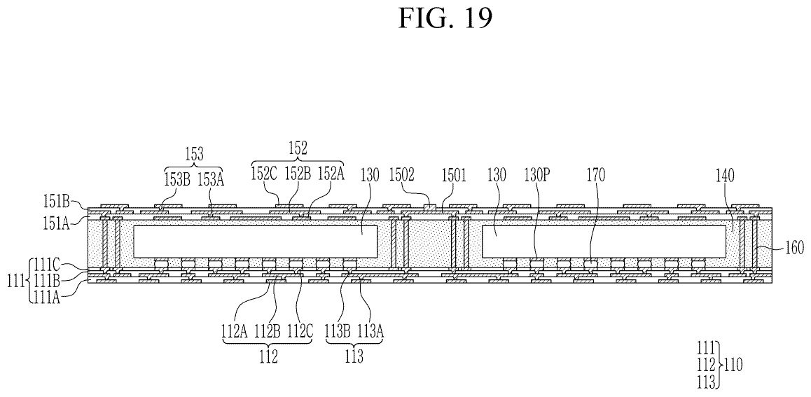

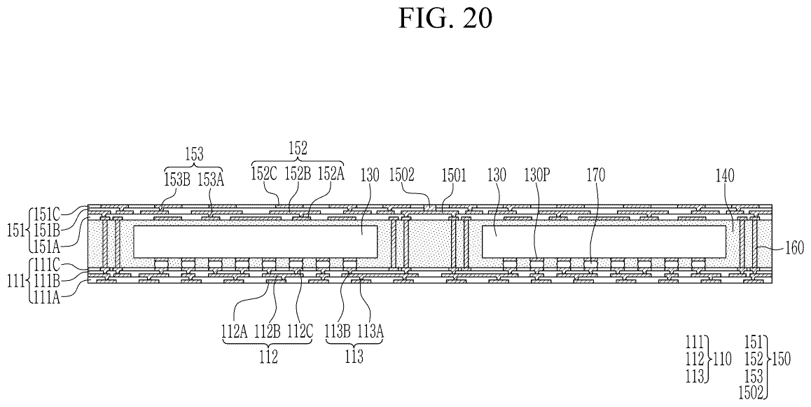

FIG. 12 to FIG. 22 are views for explaining a manufacturing method of a wafer structure according to an embodiment.

First, referring to FIG. 12, a first redistribution structure 110 is formed. The first redistribution structure 110 may be formed on, for example, a carrier wafer, and may be manufactured by sequentially forming a wiring layer 112, an insulating layer 111, and a via 113.

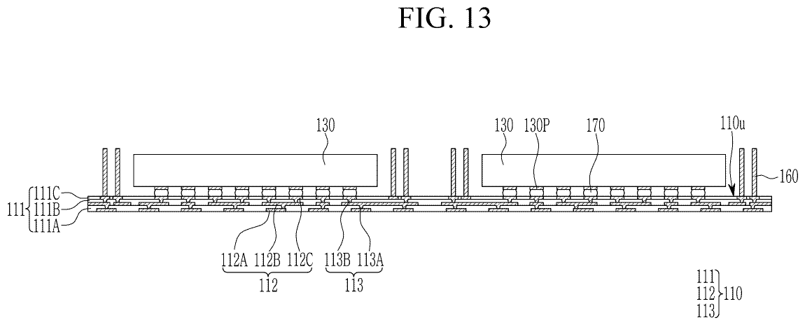

Next, referring to FIG. 13, conductive posts 160 are formed on the upper surface 110u of the first redistribution structure 110, and semiconductor chips 130 are likewise located on upper surface 110u. The conductive post 160 and the semiconductor chip 130 may be located in a region corresponding to the chip region of the wafer structure. Additionally, the semiconductor chip 130 may be mounted on the first redistribution structure 110 via the conductive bump 170.

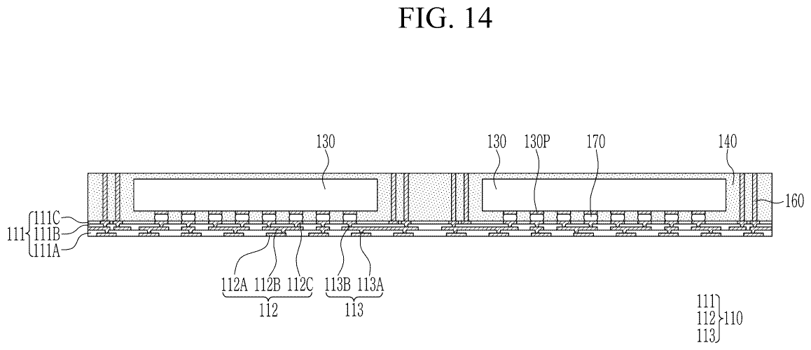

Next, referring to FIG. 14, an encapsulant 140 for encapsulating the conductive posts 160 and the semiconductor chips 130 is formed. The encapsulant 140 may be formed by a compression molding, a transfer molding, etc. At this time, the conductive post 160 may be exposed through the upper surface of the encapsulant 140 for the connection to the second redistribution structure 150. If the encapsulant 140 covers the upper surface of the conductive post 160 after the molding, an additional process of grinding the encapsulant 140 to expose the conductive post 160 may be performed.

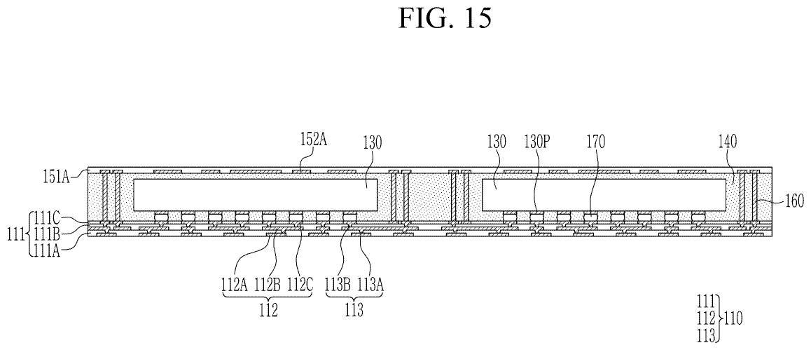

Next, referring to FIG. 15 to FIG. 20, a second redistribution structure 150 is formed on the encapsulant 140. The second redistribution structure 150 may be manufactured by sequentially forming a wiring layer 152, an insulating layer 151, and a via 153, and the wiring layer 152 may be formed to include a first conductive pattern 1501.

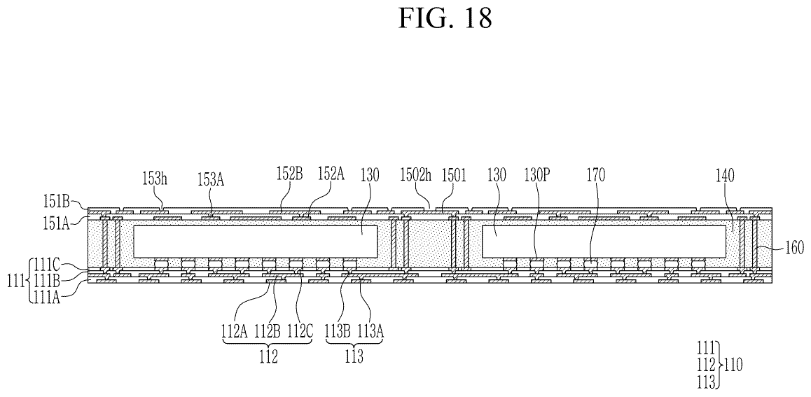

In an embodiment forming the second redistribution structure 150, the first wiring layer 152A, the first via 153A, and the first insulating layer 151A may be sequentially formed first, and the second wiring layer 152B including the first conductive pattern 1501 may be formed on the first insulating layer 151A. The first conductive pattern 1501 is formed to extend to the adjacent chip regions CA in the wafer structure and the scribe lane region SL disposed therebetween. Next, a second insulating layer 151B is formed on the first insulating layer 151A, and via holes 153h penetrating the second insulating layer 151B are formed. When forming the via hole 153h, a pattern hole 1502h (FIG. 18) for forming the second conductive pattern 1502 may be formed together. The pattern hole 1502h may be formed in a region corresponding to the scribe lane region SL of the wafer structure for example. The pattern hole 1502h may expose the first conductive pattern 1501 by penetrating the second insulating layer 151B, and may have a tapered shape, circular cylinder shape, etc. similar to the via hole 153h. Next, second vias 153B, a third wiring layer 152C, and a second conductive pattern 1502 are formed. The second vias 153B, the third wiring layer 152C and the second conductive pattern 1502 may be formed by, for example, a plating. In an embodiment, the second conductive pattern 1502 may be formed so that the width (in the region buried in the third insulating layer 151C) on the second insulating layer 151B is identical to the width (in the region buried in the second insulating layer 151B) in the region filling the pattern hole 1502h. In another embodiment, the second conductive pattern 1502 may be extended onto the second insulating layer 151B around the pattern hole 1502h, such that the width (in the region buried in the third insulating layer 151C) on the second insulating layer 151B may be wider than the width(in the region buried in the second insulating layer 151B) in the region filling the pattern hole 1502h. Next, a third insulating layer 151C may be formed to form a second redistribution structure 150.

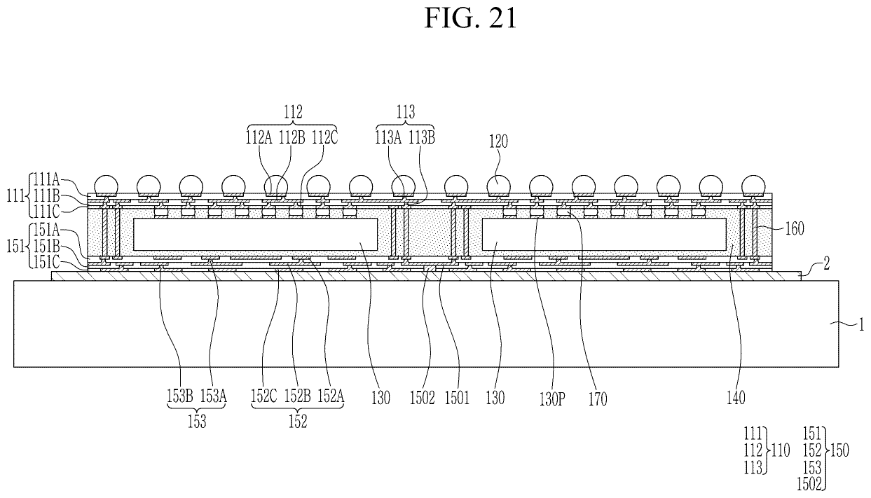

Next, referring to FIG. 21, conductive bumps 120 may be formed on the first redistribution structure 110. When forming the conductive bumps 120, the wafer structure may be fixed (e.g., a vacuum adsorption) on the table 1 with the second redistribution structure 150 attached to the tape 2.

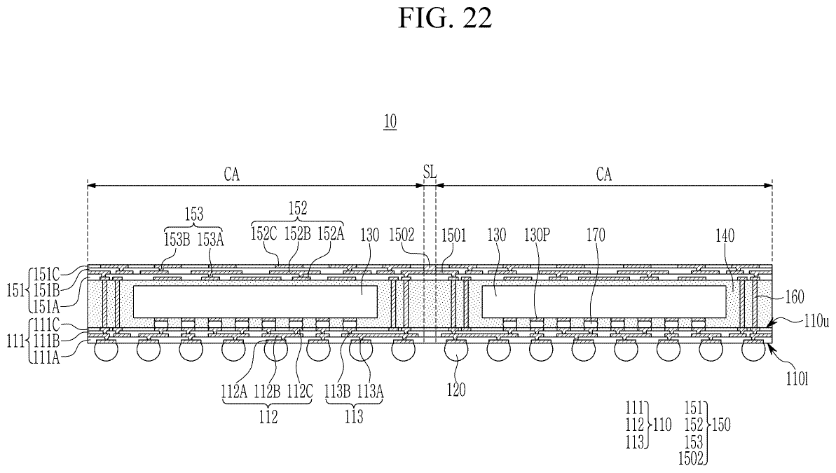

Finally, referring to FIG. 22, the tape 2 may be separated from the second redistribution structure 150 to form a wafer structure 10. The tape 2 may be separated from the second redistribution structure 150 by heat treatment, ultraviolet treatment, etc.

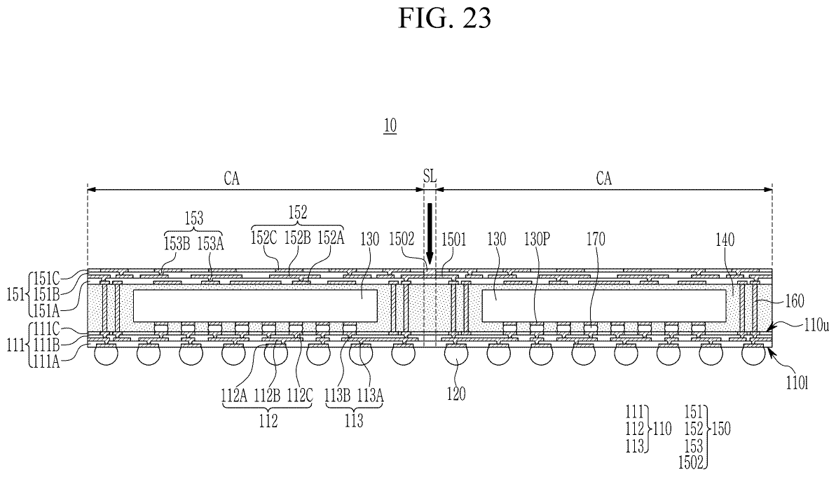

FIG. 23 is a view explaining a process of sawing a wafer structure.

The manufactured wafer structure 10 may be sawed with a blade, a laser, etc. along the scribe lane region SL, and the chip regions CA may be separated into a plurality of individual semiconductor packages. During the sawing, the region in the scribe lane region SL of each of the first conductive pattern 1501 and the second conductive pattern 1502 may be removed. Depending on the position, the width of the second conductive pattern 1502, and the process width during the sawing, the second conductive pattern 1502 may or may not remain on the semiconductor package.

FIG. 24 is a cross-sectional view of a semiconductor package according to an embodiment.

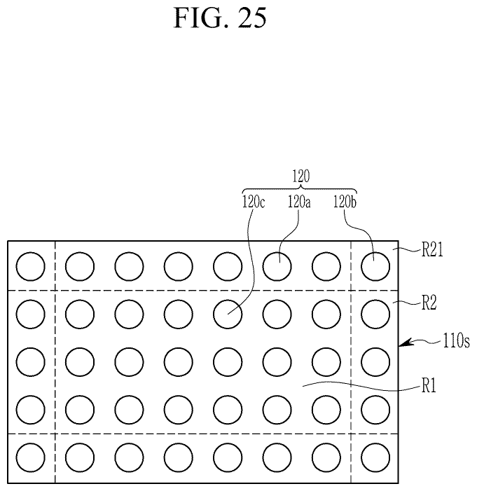

FIG. 25 is a bottom view of a semiconductor package illustrated in FIG. 24. As can be seen in FIG. 25, conductive bumps 120 are disposed within edge regions R2 and inner region R1. The edge regions R2 can be regions, for example, having the first and last conductive bump in a row or column of conductive bums on the bottom of the semiconductor package (or the first and last multiple bumps, such as the first two and last two conductive bumps in a row or column). As such, a corner region R21 can have a conductive bump(s) where a first (or last) bump(s) in a row AND a first (or last) bump(s) in a column is disposed. Or, in another example, the edge regions R2 can be regions that are within a particular percentage distance of the edge of the package. For example, in a package having a length and width, the edge regions R2 are the first and last 20% of the length (or width), or the first and last 25%, 15%, 10% etc. of the length (or width) etc. As such, the corner region R21 can have a conductive bump(s) disposed within the first or last 20% of both the length and width of the package (or within 25%, 15%, 10% etc.)

The semiconductor package 100A may include, similarly to the wafer structure 10, a first redistribution structure 110, conductive bumps 120 disposed on the lower surface 110l of the first redistribution structure 110, a semiconductor chip 130 disposed on the upper surface 110u of the first redistribution structure 110, an encapsulant 140 encapsulating at least a portion of the semiconductor chip 130, a second redistribution structure 150 disposed on the encapsulant 140, and conductive posts 160 penetrating the encapsulant 140 to electrically connect the first redistribution structure 110 and the second redistribution structure 150.

As the wafer structure 10 according to an embodiment is sawed to manufacture the semiconductor package 100A, the first conductive pattern 1501 may be exposed after sawing proximate to where the side surface 151s of the insulating layer 151 is exposed. Additionally, the side surface 110s of the first redistribution structure 110, the side surface 140s of the encapsulant 140, and the side surface 150s of the second redistribution structure 150 may be substantially coplanar. Here, the side surface 150s of the second redistribution structure 150 may include a side surface 151s of the insulating layer 151 and a surface 1501s exposed to the side surface 151s of the insulating layer 151 of the first conductive pattern 1501. As can be seen in e.g. FIG. 24, after sawing or otherwise separating chip regions (CA) from each other, these exposed side surfaces (e.g. 150s, 151s, 104s, 110s, 1501s) may be formed substantially coplanar with each other and may be substantially orthogonal to horizontally extending first redistribution structure, second redistribution structure and semiconductor chip, and these side surfaces may comprise areas that were not previously exposed prior to separating the chip regions (CA).

The first conductive pattern 1501 may be electrically connected to one or more of the conductive bumps 120. Referring to FIG. 25, in an embodiment, the first conductive pattern 1501 may be electrically connected to the conductive bump (120, the conductive bumps) arranged in the edge region R2 of the first redistribution structure 110 among the conductive bumps 120. The conductive bump arranged in the edge region R2 of the first redistribution structure 110 among the conductive bumps 120 may be the conductive bump(s) arranged at the outermost side in a plane. In an embodiment, the first conductive pattern 1501 may be electrically connected to the conductive bump (120, the conductive bumps) arranged in the corner region R21 (a region adjacent to a region where two side surfaces of the first redistribution structure 110 meet, and a region included in the edge region R2) of the first redistribution structure 110 among the conductive bumps 120. Also, the first conductive pattern 1501 may be electrically connected to the conductive bump (120, the conductive bumps) arranged in the inner region R1 among the conductive bumps 120. The drawing shows the inner region R1 of the first redistribution structure 110 and the edge region R2 surrounding the inner region R1 as distinct, but the inner region R1 and the edge region R2 of the first redistribution structure 110 do not have distinct boundaries.

The description of the first redistribution structure 110, the conductive bumps 120, the semiconductor chip 130, the encapsulant 140, the second redistribution structure 150, and the conductive post 160 may be applied identically to the description of the wafer structure 10 unless specifically contradicted.

FIG. 26 is a cross-sectional view of a semiconductor package according to another embodiment.

In the semiconductor package 100B, the second redistribution structure 150 may further include a second conductive pattern 1502 disposed on the first conductive pattern 1501 and exposed via an opening in upper surface 151u of the insulating layer 151.

When the second conductive pattern 1502 is extended to the scribe lane region SL and the chip region CA in the wafer structure, a portion of the second conductive pattern 1502 may remain in the semiconductor package after the wafer structure is sawed. At this time, the second conductive pattern 1502 can also be exposed at the side surface 150s of the of the second redistribution structure 150.

As described above, as the second conductive pattern 1502 is formed together with the second via 153B and the third wiring layer 152C, and it may be extended between the level L1 where the lower surface of the second via 153B is positioned and the level L2 where the upper surface of the third wiring layer 152C is positioned.

Additionally, the second conductive pattern 1502 may include a region embedded in the second insulating layer 151B and a region embedded in the third insulating layer 151C, and the width in the region embedded in the second insulating layer 151B of the second conductive pattern 1502 in on cross-section and the width in the region embedded in the third insulating layer 151C may be the same or different.

For other configurations, the same provisions as those described elsewhere in this specification may be applied. Unless specifically contradictory

FIG. 27 is a cross-sectional view of a semiconductor package according to another embodiment.

In the semiconductor package 100C, the second redistribution structure 150 may further include a second conductive pattern 1502 disposed on the first conductive pattern 1501 and exposed via the upper surface 151u of the insulating layer 151.

When each of the second conductive patterns 1502 in the wafer structure is positioned within each of the chip regions CA and spaced apart from each other, the second conductive pattern 1502 may remain in the semiconductor package as the wafer structure is sawed. At this time, the second conductive pattern 1502 may not be exposed at the side surface 150s of the second redistribution structure 150.

For other configurations, the same content as described elsewhere in this specification may be applied unless specifically contradictory.

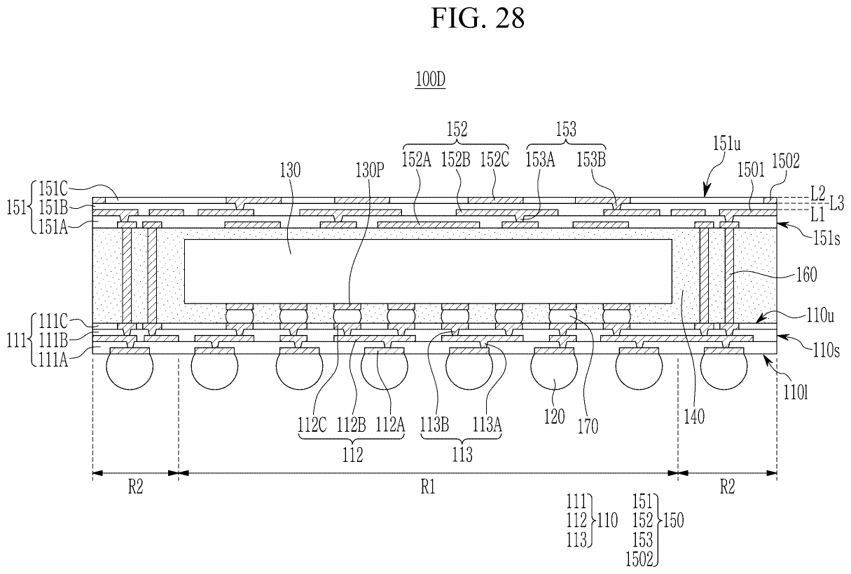

FIG. 28 is a cross-sectional view of a semiconductor package according to another embodiment.

In a semiconductor package 100D, the second conductive pattern 1502 may be positioned at the same level as the third wiring layer 152C. In other words, the second conductive pattern 1502 may be extended between a level L3, where the lower surface of the third wiring layer 152C is positioned, and a level L2, where the upper surface is positioned. When forming the second conductive pattern 1502 in the wafer structure, if the width on the second insulating layer 151B is formed wider than the width in the region filling the pattern hole 1502h, the region filling the pattern hole 1502h of the second conductive pattern 1502 may be removed during the sawing.

The second conductive pattern 1502 may be exposed at the side surface 151s and the upper surface 151u of the insulating layer 151, and the second conductive pattern 1502 may be separated from the first conductive pattern 1501 by the second insulating layer 151B.

Alternatively, the second conductive pattern 1502 may be positioned at the same level as the second via 153B, that is, at the level L1 where the lower surface of the second via 153B is positioned and at the level L3 where the upper surface of the second via 153B is positioned. When forming the second conductive pattern 1502 in the wafer structure, if the width on the second insulating layer 151B is formed narrower than the width in the region filling the pattern hole 1502h, the region formed on the second insulating layer 151B of the second conductive pattern 1502 may be removed during the sawing.

For other configurations, the same content as described elsewhere in this specification may be applied unless specifically contradictory.

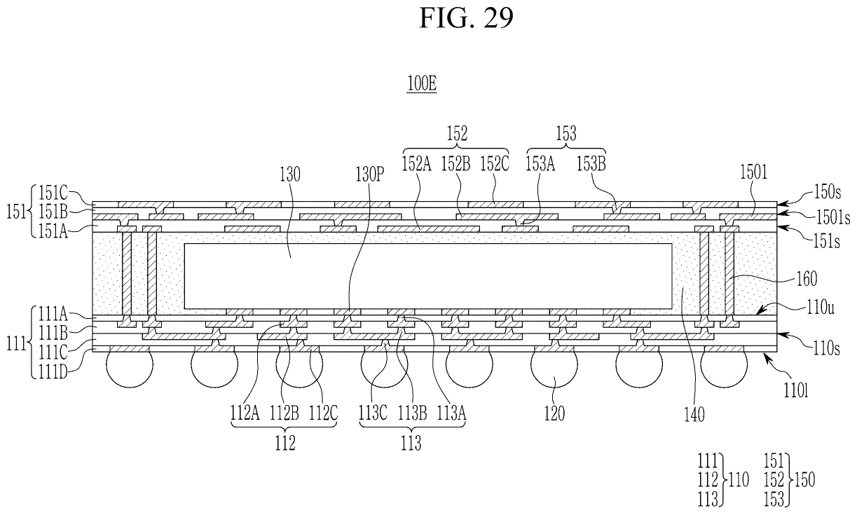

FIG. 29 is a cross-sectional view of a semiconductor package according to another embodiment.

In the semiconductor package 100E, the semiconductor chip 130 may be positioned directly on the first redistribution structure 110 without a conductive bump 170, and then a thinned semiconductor package may be provided.

The first redistribution structure 110 may include insulating layers 111, wiring layers 112, and vias 113. In the semiconductor package 100E, the conductive bumps 120 may be positioned on a surface where the fourth insulating layer 111D of the first redistribution structure 110 is positioned, and the semiconductor chip 130 may be placed on a surface where the first insulating layer 111A of the first redistribution structure 110 is positioned.

For other configurations, the same content as described elsewhere in this specification may be applied unless specifically contradictory.

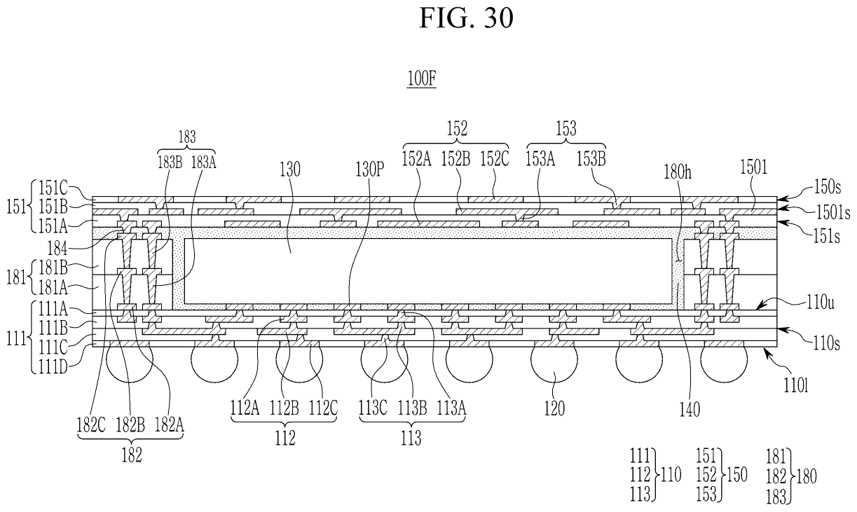

FIG. 30 is a cross-sectional view of a semiconductor package according to another embodiment.

In the semiconductor package 100F, the first redistribution structure 110 and the second redistribution structure 150 may be electrically connected through a core substrate 180 by replacing the conductive post 160, and the semiconductor package with an increased freedom in a wire design may be provided.

The core substrate 180 may have a cavity 180h penetrating between the upper and lower surfaces of the core substrate 180. The semiconductor chip 130 may be positioned within the cavity 180h and surrounded by the core substrate 180, and the encapsulant 140 may fill at least a portion of the cavity 180h.

The core substrate 180 may include insulating layers 181, wiring layers 182, and vias 183. For example, the core substrate 180 may include a first wiring layer 182A, a first insulating layer 181A covering the first wiring layer 182A, a second wiring layer 182B positioned on the first insulating layer 181A, a first via 183A electrically connecting the first wiring layer 182A and the second wiring layer 182B by penetrating the first insulating layer 181A, a second insulating layer 181B positioned on the first insulating layer 181A and covering the second wiring layer 182B, a third wiring layer 182C positioned on the second insulating layer 181B, and a second via 183B electrically connecting the second wiring layer 182B and the third wiring layer 182C by penetrating the second insulating layer 181B.

The insulating layer 181 is positioned between the wiring layers 182 to prevent electric shorts between them. The insulating layers 181 may have boundaries with each other or may not have boundaries that can be seen with a naked eye, depending on materials and manufacturing processes thereof. As the material of the insulating layer 181, an insulating material may be used, for example, polyimide (PI), epoxy, prepreg, etc. may be used.

The wiring layer 182 may include a wire pattern(s), and the wire patterns may be connected to each other to perform various functions depending on the design. For example, the wiring layers 182 may include at least one of a signal wire performing a signal transmission function, a power wire performing a power transmission function, and a ground wire performing a ground function. The number of the wiring layers 182 is not limited and may be more or less than those shown in the drawing. In addition, a conductive material may be used as the material of the wiring layer 182, and for example, copper (Cu), aluminum (Al), gold (Au), silver (Ag), platinum (Pt), tin (Sn), chromium (Cr), palladium (Pd), lead (Pb), titanium (Ti), tungsten (W) or an alloy thereof may be used.

The via 183 may provide electrical connections between the wiring layers 182 positioned at different layers. A conductive material may be used as the material for the via 183, and the same material as the material for the wiring layer 182 may be used. Depending on the manufacturing process, the via 183 may be integrally formed with the wiring layer 182, so that no boundary exists between them. Additionally, the via 183 may have a tapered shape that the width becomes narrower from one side to the other side, a circular cylinder shape, etc.

Additionally, the semiconductor package 100F may further include a connection via 184 for electrically connecting the core substrate 180 and the second redistribution structure 150. The connection via 184 may electrically connect a third wiring layer 182C, which is embedded in, for example, the encapsulant 140 and is disposed on the uppermost side of the core substrate 180, and a first wiring layer 152A, which is disposed on the lowermost side of the second redistribution structure 150.

For other configurations, the same content as described elsewhere in this specification may be applied unless specifically contradictory.

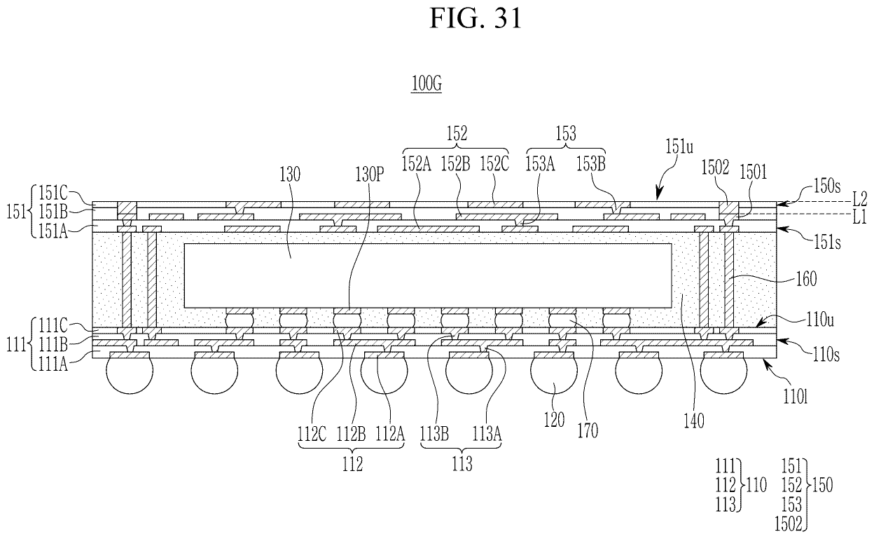

FIG. 31 is a cross-sectional view of a semiconductor package according to another embodiment.

In the semiconductor package 100G, the second redistribution structure 150 may further include a second conductive pattern 1502 disposed on the first conductive pattern 1501 and exposed to the upper surface 151u of the insulating layer 151. The second conductive pattern 1502 may provide an electron migration path from the chip region CA in the wafer structure 100 to the outside of the wafer structure 10 (e.g., the table 1).

In an embodiment, the first conductive pattern 1501 may not be exposed after sawing proximate to where the side surface 151s of the insulating layer 151 is exposed. By forming the first conductive pattern 1501 within each chip region CA in the wafer structure, the first conductive pattern 1501 may not be exposed at the side surface 150s of the second redistribution structure 150 after the sawing of the wafer structure. That is, the first conductive pattern 1501 in the wafer structure may be a wire pattern that does not provide an electron movement path between the chip regions CA.

In another embodiment, the first conductive pattern 1501 may also be exposed at the side surface 150s of the second redistribution structure 150. By elongating the first conductive pattern 1501 in the wafer structure to the scribe lane region SL and the chip region CA, the second conductive pattern 1502 may be exposed to the side surface 151s of the insulating layer 151 after sawing the wafer structure. That is, the first conductive pattern 1501 in the wafer structure may provide an electron movement path between the chip regions CA.

In an embodiment, the second conductive pattern 1502 may not be exposed at the side surface 150s of the second redistribution structure 150. By forming the second conductive pattern 1502 within each chip region CA in the wafer structure, the second conductive pattern 1502 may not be exposed to the side surface 151s of the insulating layer 151 after the sawing of the wafer structure.

In another embodiment, the second conductive pattern 1502 may also be exposed at the side surface 150s of the second redistribution structure 150. By elongating the second conductive pattern 1502 in the wafer structure to the scribe lane region SL and the chip region CA, the second conductive pattern 1502 may be exposed to the side surface 151s of the insulating layer 151 after the sawing of the wafer structure. That is, the second conductive pattern 1502 in the wafer structure not only provides an electron migration path from the chip region CA to the outside of the wafer structure 10, but may also provide an additional electron migration path between the chip regions CA.

For other configurations, the same provisions as those described elsewhere in this specification may be applied, unless otherwise specifically contradicted.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

Additionally, the embodiments of the present disclosure are not independent of each other and may be implemented in combination with each other unless specifically contradictory. Therefore, combined embodiments of the present disclosure should also be considered as included in the present disclosure.

What is claimed is:

1. A semiconductor package comprising:
a first redistribution structure;
conductive bumps arranged on a lower surface of the first redistribution structure;
a semiconductor chip arranged on an upper surface of the first redistribution structure;
an encapsulant that encapsulates at least a portion of the semiconductor chip;
a second redistribution structure disposed on the encapsulant and including an insulating layer and a first wiring layer including a first conductive pattern exposed at a side surface of the second redistribution structure; and
a conductive post that penetrates the encapsulant to electrically connect the first redistribution structure and the second redistribution structure.

2. The semiconductor package of claim 1, wherein:
the first conductive pattern is electrically connected to a conductive bump located in an edge region of the first redistribution structure among the conductive bumps.

3. The semiconductor package of claim 1, wherein:
the first conductive pattern is electrically connected to a conductive bump located in a corner region of the first redistribution structure among the conductive bumps.

4. The semiconductor package of claim 1, wherein:
the first conductive pattern is electrically connected to the semiconductor chip.

5. The semiconductor package of claim 1, wherein:
the first conductive pattern constitutes a ground wire.

6. The semiconductor package of claim 1, wherein:
the second redistribution structure further includes a second conductive pattern arranged on the first conductive pattern and exposed to an upper surface of the insulating layer.

7. The semiconductor package of claim 6, wherein:
the second conductive pattern is in contact with the first conductive pattern.

8. The semiconductor package of claim 6, wherein:
the second conductive pattern is exposed at the side surface of the second redistribution structure.

9. The semiconductor package of claim 6, wherein:
the second redistribution structure further includes a second wiring layer disposed on the first wiring layer and a via connecting the first wiring layer and the second wiring layer, and
the second conductive pattern is positioned so as to extend between a level at which a lower surface of the via is positioned and a level at which an upper surface of the second wiring layer is positioned.

10. The semiconductor package of claim 1, wherein:
a side surface of the first redistribution structure, a side surface of the encapsulant and a side surface of the second redistribution structure are coplanar, and
the side surface of the second redistribution structure includes the side surface of the insulating layer and a surface of the first conductive pattern exposed to the side surface of the insulating layer.

11. The semiconductor package of claim 1, wherein:
the semiconductor chip is arranged on the upper surface of the first redistribution structure so that connection pads face the first redistribution structure.

12. A semiconductor package comprising:
a first redistribution structure;
conductive bumps arranged on a lower surface of the first redistribution structure;
a semiconductor chip arranged on an upper surface of the first redistribution structure;
an encapsulant that encapsulates at least a portion of the semiconductor chip;
a second redistribution structure disposed on the encapsulant, and including an insulating layer, a first wiring layer including a first conductive pattern, and a second conductive pattern disposed on the first conductive pattern; and
a conductive post that penetrates the encapsulant to electrically connect the first redistribution structure and the second redistribution structure,
wherein the first conductive pattern is electrically connected to a conductive bump arranged in an edge region of the first redistribution structure among the conductive bumps, and
the second conductive pattern is electrically connected to the first conductive pattern and is exposed through an upper surface of the insulating layer.

13. The semiconductor package of claim 12, wherein:
the first conductive pattern is electrically connected to a conductive bump located at a corner region of the first redistribution structure among the conductive bumps.

14. The semiconductor package of claim 12, wherein:
the first conductive pattern is electrically connected to the semiconductor chip.

15. The semiconductor package of claim 12, wherein:
the first conductive pattern constitutes a ground wire.

16. The semiconductor package of claim 12, wherein:
the second redistribution structure further includes a second wiring layer positioned on the first wiring layer and a via connecting the first wiring layer and the second wiring layer, and
the second conductive pattern is positioned so as to extend between a level at which a lower surface of the via is positioned and a level at which an upper surface of the second wiring layer is positioned.

17. A wafer structure having chip regions and a scribe lane region disposed between the chip regions and comprising:
a first redistribution structure extended to the chip regions and the scribe lane region;
conductive bumps arranged on a lower surface of the first redistribution structure in each of the chip regions;
semiconductor chips each arranged on an upper surface of the first redistribution structure in each of the chip regions;
an encapsulant that extends to the chip regions and the scribe lane region and encapsulates at least a portion of each of the semiconductor chips;
a second redistribution structure disposed on the encapsulant so as to extend to the chip regions and the scribe lane region and including an insulating layer and a wiring layer including a first conductive pattern; and
a conductive post electrically connecting the first redistribution structure and the second redistribution structure by penetrating the encapsulant in each of the chip regions,
wherein the chip regions include a first chip region and a second chip region adjacent to each other, and
the first conductive pattern is positioned to extend to the first chip region, the second chip region, and a region positioned between the first chip region and the second chip region of the scribe lane region.

18. The wafer structure of claim 17, wherein:
the second redistribution structure further includes a second conductive pattern arranged on the first conductive pattern and exposed to an upper surface of the insulating layer.

19. The wafer structure of claim 17, wherein:
the first conductive pattern is electrically connected to a conductive bump arranged in the first chip region and a conductive bump arranged in the second chip region.

20. The wafer structure of claim 17, wherein:
the first conductive pattern is electrically connected to a semiconductor chip positioned in the first chip region and a semiconductor chip positioned in the second chip region.
